(19) United States
(12) Patent Application Publication
(10) Pub. No.: US 2009/0065924 A1
(43) Pub. Date: Mar. 12, 2009

(54) SEMICONDUCTOR PACKAGE WITH REDUCED VOLUME AND SIGNAL TRANSFER PATH

(76) Inventors: Jae Myun KIM, Gyeonggi-do (KR); Byeong Yong LIM, Seoul (KR)

Correspondence Address: LADAS & PARRY LLP, 224 SOUTH MICHIGAN AVENUE, SUITE 1600, CHICAGO, IL, 60604, US

(21) Appl. No.: 12/058,955

(22) Filed: Mar. 31, 2008

(30) Foreign Application Priority Data
Sep. 10, 2007 (KR) 10-2007-0091716

(51) Int. Cl. H01L 23/48

(52) U.S. Cl. 257/690; 257/777; 257/E23.01

(57) ABSTRACT

A semiconductor package includes a first semiconductor chip having a first semiconductor chip body including a first circuit region and peripheral regions arranged around the first circuit region. A first bonding pad group is arranged within the first circuit region and includes a plurality of bonding pads. A first redistribution group including a plurality of redistributions is electrically connected to the respective bonding pads and extends towards the peripheral regions. The package further includes a second semiconductor chip having a second semiconductor chip body including a second circuit region opposing the first circuit region. A second bonding pad group is arranged within the second circuit region and corresponds to the first bonding pad group. A second redistribution group is electrically connected to the respective bonding pads of the second bonding pad group. Redistribution connection members are used to electrically connect the first redistribution group to the second redistribution group.

### CROSS-REFERENCE TO RELATED APPLICATIONS

The present application claims priority to Korean patent application number 10-2007-0091716 filed on Sep. 10, 2007, which is incorporated herein by reference in its entirety.

### BACKGROUND OF THE INVENTION

The present invention relates to a semiconductor package, and more particularly, to a semiconductor package with a reduced volume and a reduced signal transfer path.

Recent advancements in semiconductor manufacturing technology have allowed for the development of semiconductor packages having semiconductor devices capable of processing more data in a shorter period of time.

The typical semiconductor package is manufactured by means of: a semiconductor chip manufacturing process wherein semiconductor chips are manufactured on a wafer made of a high-purity silicon; a die sorting process wherein the semiconductor chips are electrically checked; and a packaging process wherein the good semiconductor chips are packaged.

Recent developments include: a chip scale package wherein a size of the semiconductor package is only 100% to 105% of the semiconductor chip size; a stacked semiconductor package wherein a plurality of semiconductor chips are stacked upon each other improving capacity and processing speed of the semiconductor device; and a flip chip semiconductor package wherein a solder bump formed on a semiconductor chip is directly connected to a contact pad without a conductive wire.

Among these semiconductor packages, in the conventional flip chip semiconductor package a solder ball or a bump for electrically and directly connecting at least one semiconductor chip to a substrate is required. The volume of the flip chip semiconductor package having the solder ball or the bump is largely increased by the addition of the solder ball or the bump, and the signal transfer path from the semiconductor chip to the substrate is increased. The increased volume and signal transfer path act to reduce the performance of the semiconductor chip.

### SUMMARY OF THE INVENTION

Embodiments of the present invention are directed to a semiconductor package with a reduced volume and signal transfer path.

In one embodiment, a semiconductor package according to the present invention comprises: a first semiconductor chip having a first semiconductor chip body including a first circuit region and peripheral regions arranged around the first circuit region, a first bonding pad group arranged within the first circuit region and including a plurality of bonding pads, and a first redistribution group electrically connected to the respective bonding pads and including a plurality of redistributions extended to the peripheral regions; a second semiconductor chip having a second semiconductor chip body including a second circuit region opposing the first circuit region, a second bonding pad group arranged within the second circuit region and corresponding to the first bonding pad group, and a second redistribution group electrically connected to the respective second bonding pad group, projected from the second semiconductor chip body, and opposing the first redistribution group; and redistribution connection members electrically connecting the first and second redistribution groups opposing each other.

The first and second bonding pad groups of the semiconductor package are arranged in a row at the center of the first and second semiconductor chip bodies, respectively, and the first and second redistribution groups are alternately arranged on each of the first and second semiconductor chip bodies.

The first and second bonding pad groups of the semiconductor package may alternatively be arranged in two rows at the center of each of the first and second semiconductor chip bodies, respectively, and the first and second redistribution groups then extend from the center of the first and second semiconductor chip bodies to both edges thereof.

An under-fill material is interposed between the first and second semiconductor chip bodies of the semiconductor package.

Connection members are electrically connected to the second redistribution groups arranged over the second semiconductor chip body of the semiconductor package.

The semiconductor package comprises a substrate whose one side surface is provided with contact pads electrically connected to the respective connection members.

The semiconductor package further comprises ball lands arranged on the other side surface opposing the one side surface and electrically connected to the respective contact pads, and conductive balls electrically connected to the ball lands.

The first semiconductor chip includes: a first insulating film pattern interposed between the first semiconductor chip body and the first redistribution group, and the first insulating film pattern has first openings that exposes the first bonding pad groups; and a second insulating film pattern covering the first insulating pattern and having second openings exposing some of the first redistribution groups.

The second semiconductor chip includes: a third insulating film pattern interposed between the second semiconductor chip body and the second redistribution group, and the third insulating film pattern has third openings that expose the respective second bonding pad group and fourth openings that expose ends of the respective redistributions included in the second redistribution groups; and a fourth insulating film pattern covering the second redistribution group and having a fifth openings that corresponds to the fourth opening and exposes some of the second redistribution groups.

In another embodiment, the semiconductor package according to the present invention comprises: a first semiconductor chip having a first semiconductor chip body including a first circuit region and first peripheral regions arranged around the first circuit region, a first bonding pad group arranged within the first circuit region, and a first redistribution group electrically connected to the first bonding pad group and extended towards the first peripheral regions; a semiconductor chip having a second semiconductor chip body including a second circuit region and second peripheral regions arranged around the second circuit region, a second bonding pad group arranged within the second circuit region, a second redistribution group electrically connected to the second bonding pad group and extended towards the second peripheral regions, and through holes exposing the second redistribution group; redistribution connection members electrically connecting the first and second redistribution group; and connection members connected to the second redistribution groups via the through holes.

The semiconductor package includes a substrate whose one side surface is provided with the contact pads electrically connected to the respective connection members.

The first semiconductor chip of the semiconductor package includes: a first insulating film pattern interposed between the first semiconductor chip body and the first redistribution group and having first openings that expose the first bonding pad group; and a second insulating film pattern covering the first redistribution group and having second openings exposing some of the first redistribution group.

The second semiconductor chip of the semiconductor package includes: a third insulating film pattern interposed between the second semiconductor chip body and the second redistribution group and having third openings that expose the second bonding pad group and fourth openings corresponding to the through holes; and a fourth insulating film pattern covering the second redistribution group and having fifth openings corresponding to the fourth opening and exposing some of the second redistribution groups.

### BRIEF DESCRIPTION OF THE DRAWINGS

FIG. 1 is a cross-sectional view showing a semiconductor package according to an embodiment of the present invention.

FIG. 2 is a plan view showing the first semiconductor chip of FIG. 1.

FIG. 3 is a cross-sectional view taken along line I-I′ of FIG. 1.

FIG. 4 is a plan view showing the second semiconductor chip of FIG. 1.

FIG. 5 is a cross-sectional view taken along line II-II′ of FIG. 4.

FIG. 6 is a cross-sectional view showing a substrate connected to the second semiconductor chip shown in FIG. 1.

FIG. 7 a cross-sectional view showing a semiconductor package according to another embodiment of the present invention.

FIG. 8 is a plan view showing the first semiconductor chip of FIG. 7.

FIG. 9 is a plan view showing the second semiconductor chip of FIG. 7.

FIG. 10 is a cross-sectional view showing a substrate connected to the second semiconductor chip shown in FIG. 7.

### DESCRIPTION OF SPECIFIC EMBODIMENTS

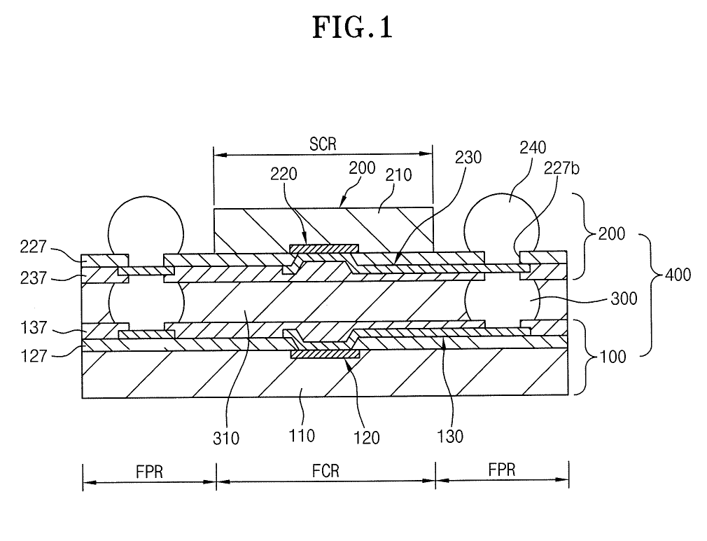

FIG. 1 is a cross-sectional view showing a semiconductor package according to an embodiment of the present invention.

Referring to FIG. 1, a semiconductor package 400 includes a first semiconductor chip 100, a second semiconductor chip 200, and a redistribution connection member 300.

The second semiconductor chip 200 is arranged on the first semiconductor chip 100, and the redistribution connection member 300 electrically connects the first semiconductor chip 100 to the second semiconductor chip 200.

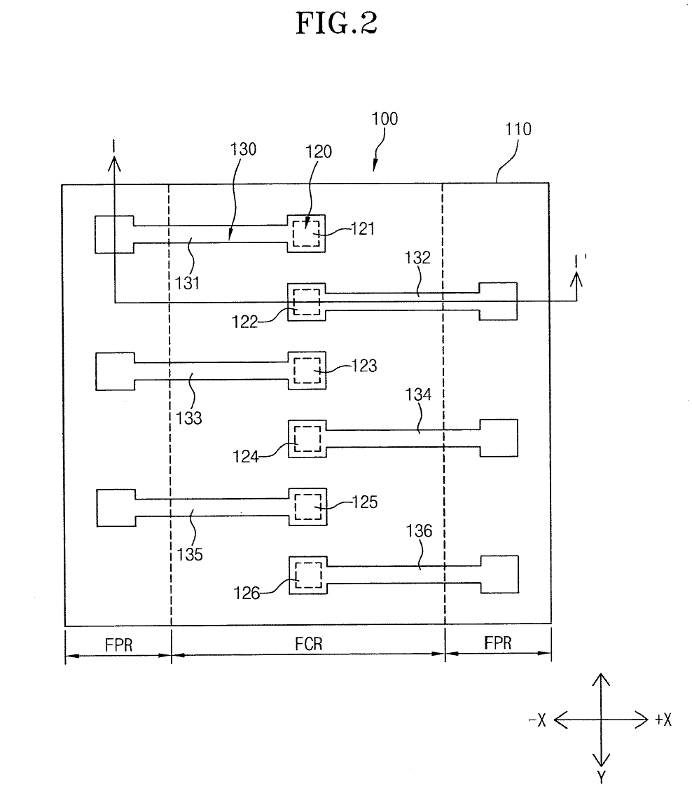

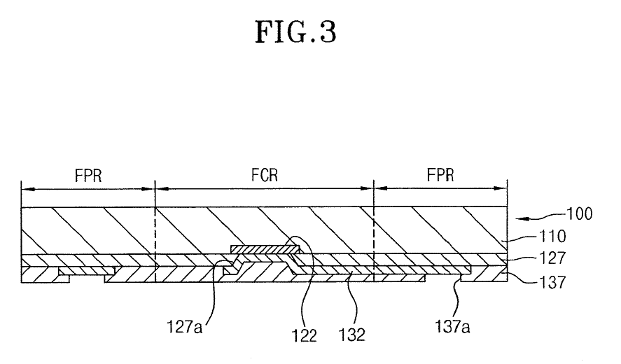

FIG. 2 is a plan view of the first semiconductor chip of FIG. 1, and FIG. 3 is a cross-sectional vie taken along line I-I′ of FIG. 1.

Referring to FIGS. 2 and 3, the first semiconductor chip 100 includes a first semiconductor chip body 110, a first bonding pad group 120, and a first redistribution group 130. Furthermore, the first semiconductor chip 100 includes a first insulating film pattern 127 and a second insulating film pattern 137 as shown in FIG. 3.

The first semiconductor chip body 110 has, for example, a rectangular parallelepiped shape. The first semiconductor chip body 110 having the rectangular parallelepiped shape includes a first circuit region (FCR) having a data storage unit (not shown) and/or a data processing unit (not shown), and peripheral regions (FPR) arranged around the first circuit region (FCR). In the present embodiment, the peripheral region (FPR) may be a cutting region for separating the first semiconductor chip 100 from a wafer. The peripheral region (FPR) may have a width of about 100 μm.

In the present embodiment, the first circuit region (FCR) is arranged at the center of the first semiconductor chip body 110, and the peripheral regions (FPR) are arranged at both sides of the first circuit region FCR, respectively.

The first bonding pad group 120 is arranged, for example, within the first circuit region (FCR). The first bonding pad group 120 includes a plurality of bonding pads. The bonding pads included in the first bonding pad group 120 are arranged in a row along the Y axis direction shown in FIG. 2

In the present embodiment, the first bonding pad group 120 shown in FIG. 2 is includes, as an example, six bonding pads. Hereinafter, the six bonding pads are defined as first to sixth bonding pads 121, 122, 123, 124, 125, 126.

Although in the present embodiment as shown in FIG. 2, only six bonding pads 121-126 are arranged within the first circuit region (FCR), the first bonding pad group 120 may include seven or more bonding pads.

Additionally, although in the present embodiment as shown in FIG. 2, the first to sixth bonding pads 121-126 included in the first bonding pad group 120 are arranged in a row along the Y axis direction, the first to sixth bonding pads 121, 122, 123, 124, 125, 126 included in the first bonding pad group 120 may alternatively be arranged in two rows with each row being arranged along the Y axis direction.

The first insulating film pattern 127 is arranged on the surface of the first semiconductor chip body 110 having the first bonding pad group 120 formed thereon. The first insulating film pattern 127 has first openings 127a exposing the first to sixth bonding pads 121-126 of the first bonding pad group 120. The first insulating film pattern 127 includes an organic film.

The first redistribution group 130 is arranged on the first insulating film pattern 127. The first redistribution group 130 includes a plurality of redistributions each being electrically connected to a respective one of the first to sixth bonding pads 121-126 included in the first bonding pad group 120.

Hereinafter, the redistributions included in the first redistribution group 130, which are electrically connected to the first to sixth bonding pads 121-126, are defined as first to sixth redistributions 131, 132, 133, 134, 135, 136.

First side ends of the first redistribution 131, the third redistribution 133, and the fifth redistribution 135 are electrically connected to the first bonding pad 121, the third bonding pad 123, and the fifth bonding pad 125 respectively through the first openings 127a of the first insulating film pattern 127. Second side ends, which oppose the first side ends, of the first redistribution 131, the third redistribution 133, and the fifth redistribution 135 extend in the −X axis direction shown in FIG. 2.

Meanwhile, first side ends of the second redistribution 132, the fourth redistribution 134, and the sixth redistribution 135 are electrically connected to the second bonding pad 122, the fourth bonding pad 124, and the sixth bonding pad 126 respectively through the first openings 127a of the first insulating film pattern 127. Second side ends, which oppose the first side ends, of the second redistribution 132, the fourth redistribution 134, and the sixth redistribution 136 extend in the +X axis direction shown in FIG. 2.

The second insulating film pattern 137 is arranged on the first insulating film pattern 127 to cover the first redistribution group 130. The second insulating film pattern 137 has second openings 137a exposing the second side ends of the first to sixth redistributions 131-137 arranged on the first insulating film pattern 127.

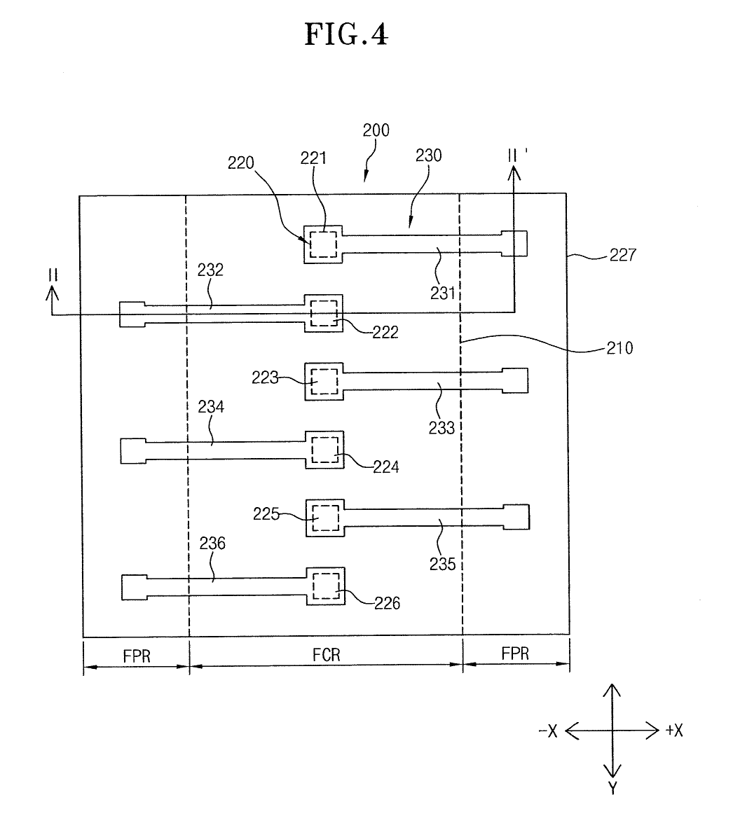

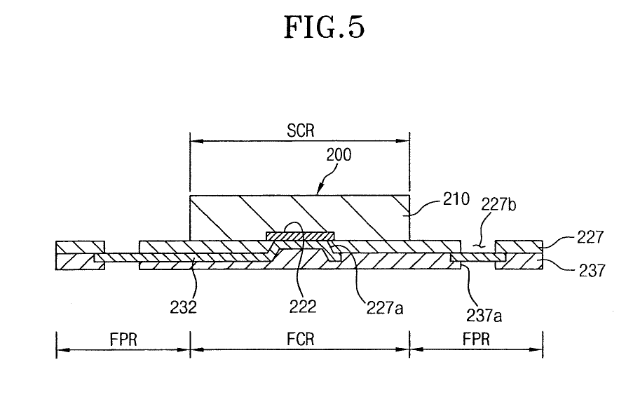

FIG. 4 is a plan view of the second semiconductor chip of FIG. 1. FIG. 5 is a cross-sectional view taken along line II-II′ of FIG. 4.

Referring to FIGS. 4 and 5, the second semiconductor chip 200 includes a second semiconductor chip body 210, a second bonding pad group 220, and a second redistribution group 230. Furthermore, the second semiconductor chip 200 includes a third insulating film pattern 227 and a fourth insulating film pattern 237.

The second semiconductor chip body 210 has, for example, a rectangular parallelepiped shape. The second semiconductor chip body 210 having the rectangular parallelepiped shape includes a data storage unit (not shown) and/or a data processing unit (not shown). In the present embodiment, the second semiconductor chip body 210 is arranged in a second circuit region (SCR) corresponding to the first circuit region (FCR).

The second bonding pad group 220 is arranged, for example, within the second circuit region (SCR). The second bonding pad group 220 includes a plurality of bonding pads. The bonding pads included in the second bonding pad group 220 are arranged in a row along the Y axis direction shown in FIG. 4.

In the present embodiment, the second bonding pad group 120 includes, for example, the same number of bonding pads as the first bonding pad group 120 of the first semiconductor chip 100. Accordingly, in the present embodiment, since the first bonding pad group 120 includes, for example, six bonding pads, the second bonding pad group 220 also includes six bonding pads.

Hereinafter, the six bonding pads included in the second bonding pad group 220 are defined as seventh to twelfth bonding pads 221, 222, 223, 224, 225, 226.

Although in the present embodiment only six bonding pads 221-226 are arranged within the second circuit region (SCR), the second bonding pad group 220 may include seven or more bonding pads.

Additionally, although in the present embodiment the seventh to twelfth bonding pads 221-226 included in the second bonding pad group 220 are arranged in a row along the Y axis direction, alternatively, the seventh to twelfth bonding pads 221-226 included in the second bonding pad group 220 may be arranged in two rows with each row being arranged along the Y axis direction shown in FIG. 4.

The third insulating film pattern 227 is arranged on the surface on which the second bonding pad group 220 is formed. The third insulating film pattern 227 has third openings 227a exposing the second bonding pad group 220 and fourth openings 227b corresponding to a second openings 137a formed in the second insulating film pattern 137 of the first semiconductor chip 100. The third insulating film pattern 227 includes an organic film. In the present embodiment, the third insulating film pattern 227 has substantially the same shape and size as the first insulating film pattern 127 of the first semiconductor chip 100. Therefore, the third insulating film pattern 227 has a size larger than that of the second semiconductor chip body 210.

The second redistribution group 230 is arranged on the third insulating film pattern 227.

The second redistribution group 230 includes a plurality of redistributions each electrically connected to a respective one of the seventh to twelfth bonding pads 221-226 included in the second bonding pad group 220.

Hereinafter, the redistributions included in the second redistribution group 230, which are electrically connected to a respective one of the seventh to twelfth bonding pads 221-226, are defined as seventh to twelfth redistributions 231, 232, 233, 234, 235, 236.

First side ends of the eighth redistribution 232, the tenth redistribution 234, and the twelfth redistribution 236 are electrically connected to the eighth bonding pad 222, the tenth bonding pad 224, and the twelfth bonding pad 226 respectively. Second side ends, which oppose the first side ends, of the eighth redistribution 232, the tenth redistribution 234, and the twelfth redistribution 236 extend in the −X axis direction shown in FIG. 4. As such, the eighth redistribution 232, the tenth redistribution 234, and the twelfth redistribution 236 extend towards an edge of the peripheral region (FPR).

Meanwhile, first side ends of the seventh redistribution 231, the ninth redistribution 233, and the eleventh redistribution 235 are electrically connected to the seventh bonding pad 221, the ninth bonding pad 223, and the eleventh bonding pad 225 respectively. Second ends, which oppose the first ends, of the seventh redistribution 231, the ninth redistribution 233, and the eleventh redistribution 235 extend in the +X-axis direction shown in FIG. 4. The seventh redistribution 231, the ninth redistribution 233, and the eleventh redistribution 235 extend towards edges of the peripheral regions (FPR) of the third insulating film pattern 227.

The fourth insulating film pattern 237 is arranged on the third insulating film pattern 227. The fourth insulating film pattern 237 has fifth openings 237a exposing the second side ends of the seventh to twelfth redistributions 231-237 arranged on the third insulating film pattern 227. The fifth openings 237a of the third insulating film pattern 227 are arranged at a position opposite to the second openings 137a of the second insulating film pattern 137.

In the present embodiment, the first redistribution group 120 of the first semiconductor chip 100 and the second redistribution group 220 of the second semiconductor chip 200 have, for example, a shape that is symmetrical to each other. Therefore, the first redistribution group 120 of the first semiconductor chip 100 and the second redistribution group 220 of the second semiconductor chip 200 are arranged such that they are opposite to each other. Accordingly, when the first semiconductor chip 100 and the second semiconductor chip 200 are arranged to oppose each other, the first redistribution group 120 of the first semiconductor chip 100 and the second redistribution group 220 of the second semiconductor chip 200 overlap at the same position.

Referring back to FIG. 1, a redistribution connection member 300 is interposed between the first redistribution group 120 of the first semiconductor chip 100 and the second redistribution group 220 of the second semiconductor chip 200 (which are opposite to each other) so that the first redistribution group 130 and the second redistribution group 230 are electrically connected via the redistribution connection member 300.

In the present embodiment, the redistribution connection member 300 may be, for example, a solder ball including a solder. Alternatively, the redistribution connection member 300 may be a conductive tape including adhesion materials and conductive materials. Alternatively, the redistribution connection member 300 may be a resin and an anisotropic conductive film (ACF) including conductive balls having a micro diameter.

An under-fill member 310 may be arranged between the first semiconductor chip 100 and the second semiconductor chip 200 connected to each other via the redistribution connection member 300. The under-fill member 310 insulates the first and second semiconductor chips 100, 200 and prevents damage to the redistribution connection member 300 caused by externally applied vibration and/or impact.

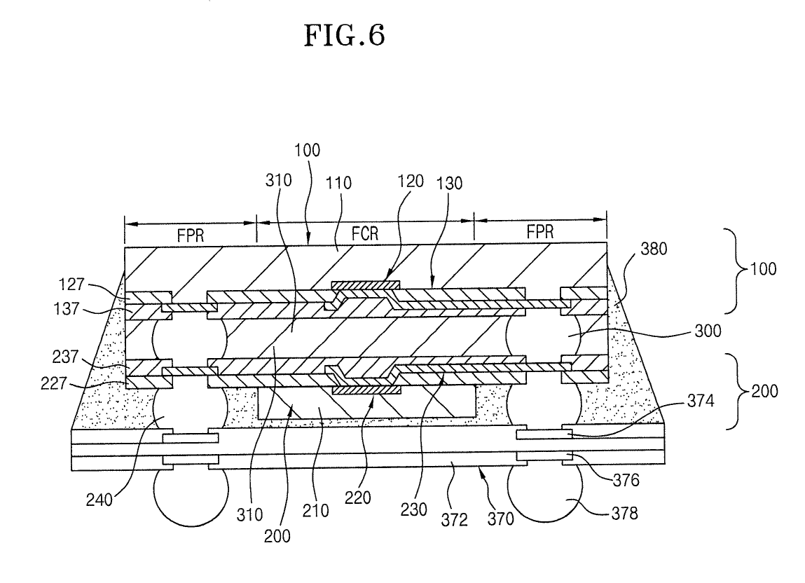

FIG. 6 is a cross-sectional view showing a substrate connected to the second semiconductor chip shown in FIG. 1.

Referring to FIG. 6, the second redistribution group 230 exposed by the fifth openings 237a in the third insulating film pattern 237 of the semiconductor chip 200 shown in FIG. 1 is electrically connected to a connection member 240. The connection member 240 has a diameter larger than the thickness of the second semiconductor chip 200, so that the connection member 240 projects from the upper surface of the second semiconductor chip 200.

The connection member 240 attached to the second semiconductor chip 200 is electrically connected to a contact pad 374 arranged on the upper surface of the substrate body 372 of the substrate 370. The contact pad 374 is electrically connected to a ball land 376 arranged on the lower surface (which opposes the upper surface) of the substrate body 372. The ball land 376 is electrically connected to a solder ball 378.

A molding member 380 covering the first and second semiconductor chips 100, 200 is arranged on the sides of the first and second semiconductor chips 100, 200 and the upper surface of the substrate 370.

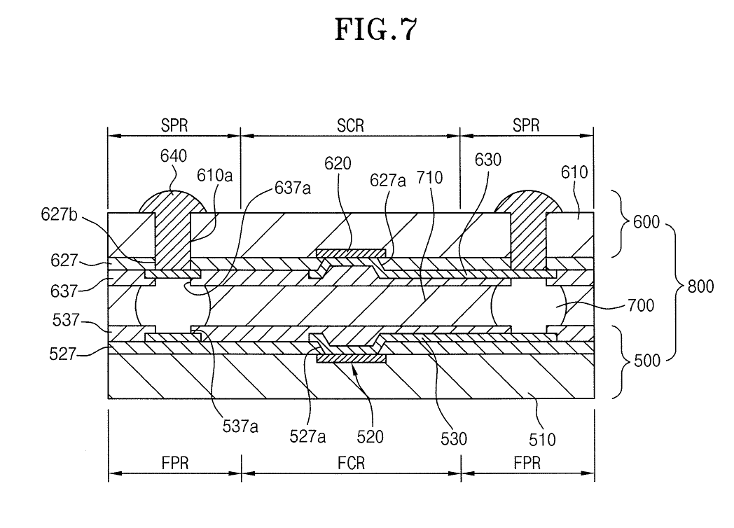

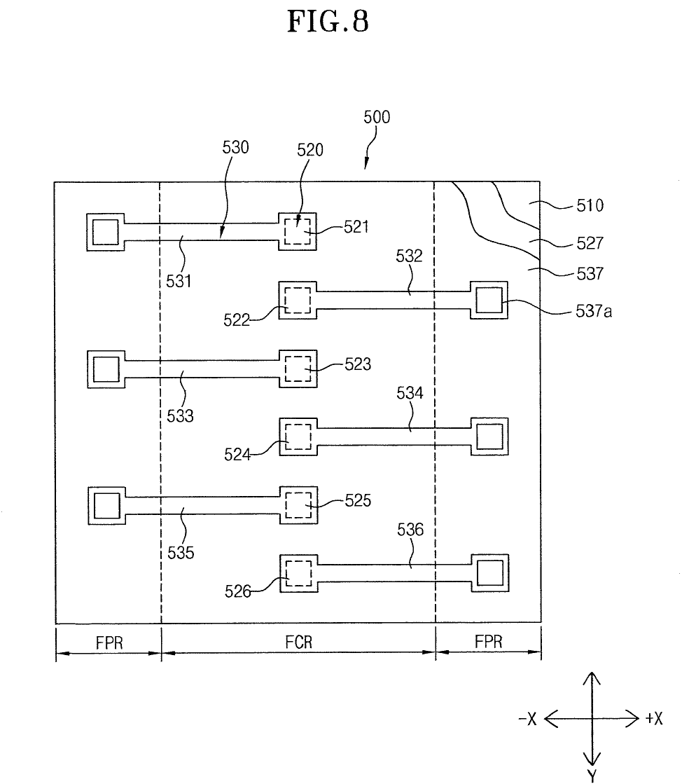

FIG. 7 is a cross-sectional view of a semiconductor package according to a second embodiment of the present invention. FIG. 8 is a plan view showing the first semiconductor chip of FIG. 7.

Referring to FIGS. 7 and 8, a semiconductor package 800 includes a first semiconductor chip 500, a second semiconductor chip 600, and a redistribution connection member 700.

The second semiconductor chip 600 is arranged on the first semiconductor chip 500, and the redistribution connection member 700 electrically connects the first semiconductor chip 500 to the second semiconductor chip 600.

The first semiconductor chip 500 includes a first semiconductor chip body 510, a first bonding pad group 520, and a first redistribution group 530. In addition, the first semiconductor chip 500 includes a first insulating film pattern 527 and a second insulating film pattern 537.

The first semiconductor chip body 510 has, for example, a rectangular parallelepiped shape. The first semiconductor chip body 510 having the rectangular parallelepiped shape includes a first circuit region (FCR) having a data storage unit (not shown) and/or a data processing unit (not shown), and first peripheral regions (FPR) arranged around the first circuit region (FCR).

In the present embodiment, the first peripheral region (FPR) may be a cutting region for separating the first semiconductor chip 500 from a wafer. The first peripheral region (FPR) may have a width of about 100 μm.

In the present embodiment, the first circuit region (FCR) is arranged at the center of the first semiconductor chip body 510, and the first peripheral regions (FPR) are arranged at both sides of the first circuit region FCR, respectively.

The first bonding pad group 520 is arranged, for example, within the first circuit region (FCR). The first bonding pad group 520 includes a plurality of bonding pads. The bonding pads included in the first bonding pad groups 520 are arranged, for example, in a row along the Y axis direction of the first circuit region (FCR) shown in FIG. 2.

In the present embodiment, the first bonding pad group 520 includes, as an example, six bonding pads. Hereinafter, the six bonding pads are defined as first to sixth bonding pads 521, 522, 523, 524, 525, 526.

Although in the present embodiment as shown in FIG. 8, only six bonding pads 521-526 are arranged within the first circuit region (FCR), the first bonding pad group 520 may include seven or more bonding pads.

Additionally, although in the present embodiment the first to sixth bonding pads 521-526 included in the first bonding pad group 520 are arranged in a row along the Y axis direction shown in FIG. 8, the first to sixth bonding pads 521-526 included in the first bonding pad group 520 may alternatively be arranged in two rows with each row being arranged along the Y axis direction.

The first insulating film pattern 527 is arranged on the surface of the first semiconductor chip body 510 having the first bonding pad group 520 formed thereon. The first insulating film pattern 527 has first openings 527a exposing the first to sixth bonding pads 521-526 of the first bonding pad group 520. The first insulating film pattern 527 includes an organic film.

The first redistribution group 530 is arranged on the first insulating film pattern 527. The first redistribution group 530 includes a plurality of redistributions each being electrically connected to a respective one of the first to sixth bonding pads 521-526 included in the first bonding pad group 520.

Hereinafter, the redistributions included in the first redistribution group 530, which are electrically connected to the first to sixth bonding pads 521-526, are defined as first to sixth redistributions 531, 532, 533, 534, 535, 536.

First side ends of the first redistribution 531, the third redistribution 533, and the fifth redistribution 535 are electrically connected to the first bonding pad 521, the third bonding pad 523, and the fifth bonding pad 525 respectively through the first openings 527a of the first insulating film pattern 527. Second side ends, which oppose the first side ends, of the first redistribution 531, the third redistribution 533, and the fifth redistribution 535 extend in the −X axis direction shown in FIG. 8.

Meanwhile, first side ends of the second redistribution 532, the fourth redistribution 534, and the sixth redistribution 535 are electrically connected to the second bonding pad 522, the fourth bonding pad 524, and the sixth bonding pad 526 respectively through the first openings 527a of the first insulating film pattern 527. Second side ends, which oppose the first side ends, of the second redistribution 532, the fourth redistribution 534, and the sixth redistribution 536 extend in the +X axis direction shown in FIG. 8.

The second insulating film pattern 537 is arranged on the first insulating film pattern 527. The second insulating film pattern 537 has a second opening 537a exposing the second ends of the first to sixth redistributions 531-537 arranged on the first insulating film pattern 527.

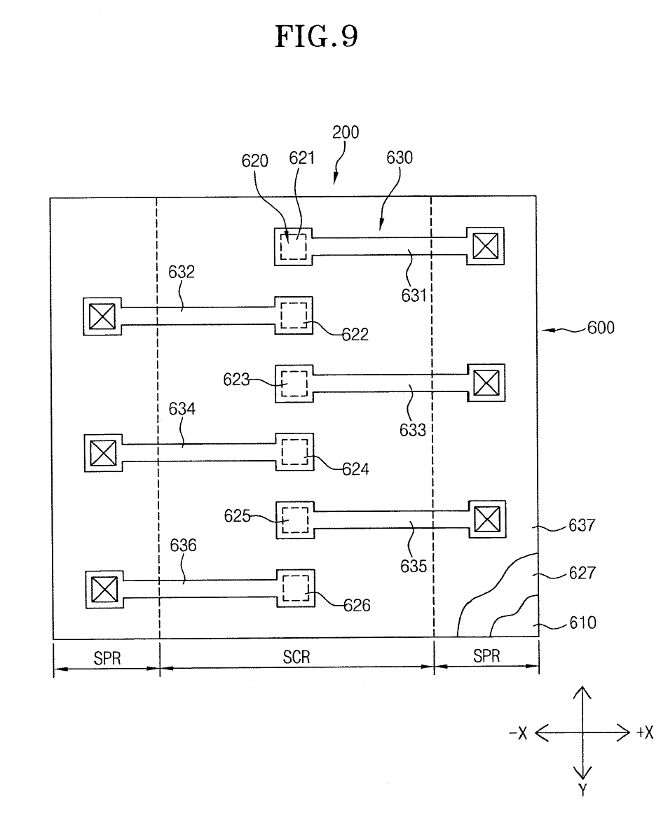

FIG. 9 is a plan view of the second semiconductor chip of FIG. 7.

Referring to FIGS. 7 and 9, the second semiconductor chip 600 includes a second semiconductor chip body 610, a second bonding pad group 620, and a second redistribution group 630. Furthermore, the second semiconductor chip 600 includes a third insulating film pattern 627 and a fourth insulating film pattern 637

The second semiconductor chip body 610 has, for example, a rectangular parallelepiped shape. The second semiconductor chip body 610 having the rectangular parallelepiped shape includes a data storage unit (not shown) and/or a data processing unit (not shown). Further, the second semiconductor chip body 610 includes a second circuit region (SCR) having the same shape and area as the first circuit region (FCR) and a second peripheral region (SPR). The second peripheral region (SPR) is on both sides of the second circuit region (SCR).

In the present embodiment, the second semiconductor chip body 610 has through holes 610a corresponding to the second openings 537a formed in the second insulating pattern 537.

The second bonding pad group 620 is arranged, for example, within the second circuit region (SCR). The second bonding pad group 620 includes a plurality of bonding pads. The bonding pads included in the second bonding pad group 620 are arranged in a row along the Y axis direction shown in FIG. 9

In the present embodiment, the second bonding pad group 620 includes, for example, the same number of bonding pads as the first bonding pad group 620. Accordingly, in the present embodiment, when the first bonding pad group 520 includes, for example, six bonding pads, the second bonding pad group 620 also includes six bonding pads.

Hereinafter, the six bonding pads included in the second bonding pad group 620 are defined as seventh to twelfth bonding pads 621, 622, 623, 624, 625, 626.

Although in the present embodiment only six bonding pads 621-626 are arranged within the second circuit region (SCR), the second bonding pad group 620 may include seven or more bonding pads.

Additionally, although in the present embodiment the seventh to twelfth bonding pads 621-626 included in the second bonding pad group 220 are arranged in a row along the Y axis direction shown in FIG. 9, alternatively, the seventh to twelfth bonding pads 621-626 included in the second bonding pad group 620 may be arranged in two rows with each row being arranged along the Y axis direction shown in FIG. 9.

The third insulating film pattern 627 is arranged on the surface of the second semiconductor chip body 610 on which the second bonding pad group 620 is formed. The third insulating film pattern 627 has third openings 627a exposing the bonding pads 621-626 of the second bonding pad group 620, and fourth openings 627b corresponding to the second openings 537a formed in the second insulating film pattern 537 of the first semiconductor chip. The third insulating film pattern 627 includes an organic film.

The second redistribution group 630 is arranged on the third insulating pattern 627.

The second redistribution group 630 includes a plurality of redistributions each being electrically connected to a respective one of the seventh to twelfth bonding pads 621-626 included in the second bonding pad group 620.

Hereinafter, the redistributions included in the second redistribution group 630, which are electrically connected to the respective seventh to twelfth bonding pads 621-626, are defined as seventh to twelfth redistributions 631, 632, 633, 634, 635, 636.

First side ends of the eighth redistribution 632, the tenth redistribution 634, and the twelfth redistribution 636 are electrically connected to the eighth bonding pad 622, the tenth bonding pad 624, and the twelfth bonding pad 626 respectively. Second side ends, which oppose the first side ends, of the eighth redistribution 632, the tenth redistribution 634, and the twelfth redistribution 636 extend in the −X axis direction shown in FIG. 9. The eighth redistribution 632, the tenth redistribution 634, and the twelfth redistribution 636 extend towards edges of the second peripheral regions (SPR).

Meanwhile, first side ends of the seventh redistribution 631, the ninth redistribution 633, and the eleventh redistribution 635 are electrically connected to the seven bonding pad 621, the nine bonding pad 623, and the eleven bonding pad 625 respectively. Second ends, which oppose the first ends, of the seventh redistribution 631, the ninth redistribution 633, and the eleventh redistribution 635 extend in the +X-axis direction shown in FIG. 9. The seventh redistribution 631, the ninth redistribution 633, and the eleventh redistribution 635 extend towards edges of the second peripheral regions (SPR) of the third insulating film pattern 627.

The second ends of the seventh to twelfth redistributions 631-636 are arranged in a position corresponding to each through hole 610a formed in the second semiconductor chip body 610, so that the second ends of the seventh to twelfth redistributions 631-636 are exposed by the through hole 610a.

The fourth insulating film pattern 637 is arranged on the third insulating film pattern 627. The fourth insulating film pattern 637 has a fifth opening 637a exposing the second ends of the seventh to twelfth redistributions 631-637 arranged on the third insulating film pattern 627. The fifth opening 637a of the fourth insulating film pattern 637 is arranged at a position corresponding to the through hole 610a of the second chip body 610.

In the present embodiment, the first redistribution group 520 of the first semiconductor chip 500 and the second redistribution group 620 of the second semiconductor chip 600 have, for example, a shape that is symmetrical to each other. Therefore, when the first semiconductor chip 500 and the second semiconductor chip 600 are arranged to oppose each other, the first redistribution group 520 of the first semiconductor chip 500 and the second redistribution group 620 of the second semiconductor chip 600 overlap at the same position.

Referring back to FIG. 7, the redistribution connection member 700 is interposed between the first redistribution group 530 of the first semiconductor chip 500 and the second redistribution group 630 of the second semiconductor chip 600 (which are opposite to each other) so that the first redistribution group 530 and the second redistribution group 630 are electrically connected via the redistribution connection member 700.

In the present embodiment, the redistribution connection member 700 may be, for example, a solder ball including a solder. Alternatively, the redistribution connection member 700 may be a conductive tape including adhesion materials and conductive materials. Alternatively, the redistribution connection member 700 may be a resin and an anisotropic conductive film (ACF) including conductive balls.

An under-fill member 710 may be arranged between the first semiconductor chip 500 and the second semiconductor chip 600 connected to each other by the redistribution connection member 700. The under-fill member 710 insulates the first and second semiconductor chips 500, 600 and prevents damage to the redistribution connection member 700 caused by externally applied vibration and/or impact.

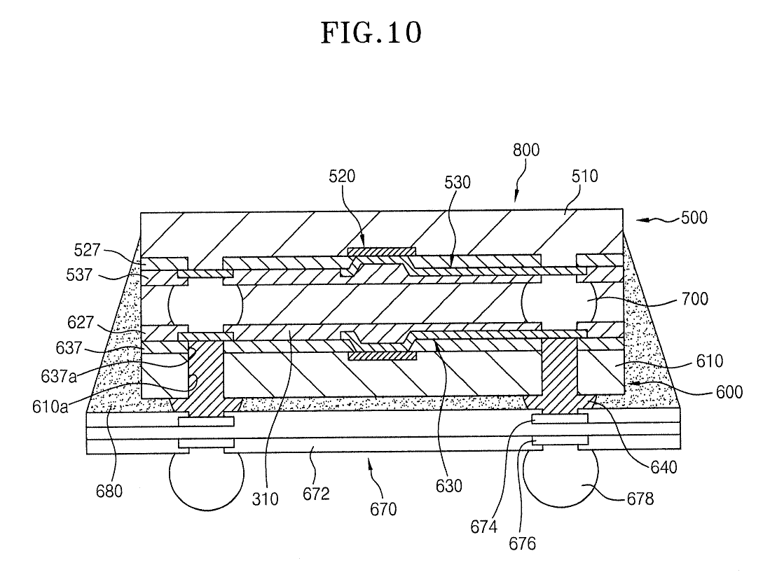

FIG. 10 is a cross-sectional view showing a substrate connected to the second semiconductor chip shown in FIG. 7.

Referring to FIG. 10, the second redistribution group 630, which is exposed by the through hole 610a penetrating through the second semiconductor chip body 610 and the fifth opening 637a in the fourth insulating film pattern 237, is electrically connected to a connection member 640. As is shown in FIG. 10, the connection member 640 projects from the second semiconductor chip 600.

The connection member 640 attached to the second semiconductor chip 600 is electrically connected to a contact pad 674 arranged on the upper surface of the substrate body 672 of the substrate 670, and the contact pad 674 is electrically connected to a ball land 676 arranged on the lower surface (which is opposite to the upper surface) of the substrate body 672. The ball land 676 is electrically connected to a solder ball 678.

A molding member 680 covering the first and second semiconductor chips 500, 600 is arranged on the side surfaces of the first and second semiconductor chips 500, 600 and the upper surface of the substrate 670.

As is apparent from the above detailed description, the present invention reduces both the volume of a semiconductor package and the distance of the signal transfer path between the semiconductor chip and the substrate thereby improving the operating speed of the semiconductor package.

Although specific embodiments of the present invention have been described for illustrative purposes, those skilled in the art will appreciate that various modifications, additions, and substitutions are possible without departing from the scope and the spirit of the invention as disclosed in the accompanying claims.

What is claimed is:

1. A semiconductor package comprising:
a first semiconductor chip having a first semiconductor chip body including a first circuit region and peripheral regions arranged around the first circuit region, the first semiconductor chip comprising:
a first bonding pad group arranged within the first circuit region, the first bonding pad group comprising a plurality of bonding pads; and
a first redistribution group comprising a plurality of redistributions, each redistribution being electrically connected to a respective one of the bonding pads of the first bonding pad group, wherein the redistributions of the first redistribution group extend to the peripheral regions;
a second semiconductor chip having a second semiconductor chip body including a second circuit region facing the first circuit region, the second semiconductor chip comprising:
a second bonding pad group arranged within the second circuit region, the second bonding pad group comprising a plurality of bonding pads corresponding to the bonding pads of the first bonding pad group, and
a second redistribution group comprising a plurality of redistributions, each redistribution of the second redistribution group being electrically connected to a respective one of the bonding pads of the second bonding pad group, wherein the second redistribution group faces the first redistribution group; and
a plurality of redistribution connection members electrically connecting the facing redistributions of the first and second redistribution group.

2. The semiconductor package according to claim 1, wherein the bonding pads of the first bonding pad group and the second bonding pad group are arranged in a row at the center of the first and second semiconductor chip bodies, respectively, and wherein the redistributions of the first redistribution group alternately extend in opposed directions and the redistributions of the second redistribution group alternately extend in opposed directions on the first and second semiconductor chip bodies.

3. The semiconductor package according to claim 1, wherein each of the first and second bonding pad groups are arranged in two rows at the center of the respective first and second semiconductor chip bodies, and the redistributions of the first and second redistribution groups extend from the center of the respective first and second semiconductor chip bodies towards both edges of the respective first and second semiconductor chip bodies.

4. The semiconductor package according to claim 1, wherein an under-fill material is interposed between the first and second semiconductor chip bodies of the semiconductor package.

5. The semiconductor package according to claim 1, further comprising connection members being electrically connected to the redistributions of the second redistribution group.

6. The semiconductor package according to claim 5, further comprising a substrate having a first surface provided with a plurality of contact pads, wherein each of the contact pads is electrically connected to a respective one of the connection members.

7. The semiconductor package according to claim 6, further comprising:
a plurality of ball lands arranged on a second surface of the substrate opposite to the first surface, the ball land being electrically connected to a respective the contact pad; and
a plurality of conductive balls each being electrically connected to a respective one of the ball lands.

8. The semiconductor package according to claim 1, wherein the first semiconductor chip further comprises:
a first insulating film pattern interposed between the first semiconductor chip body and the first redistribution group, the first insulating film pattern having a plurality of first openings exposing the bonding pads of the first bonding pad group; and
a second insulating film pattern covering the first redistribution group, the second insulating film pattern having a plurality of second openings exposing portions of the redistributions of the first redistribution group.

9. The semiconductor package according to claim 1, wherein the second semiconductor chip further comprises:
a third insulating film pattern interposed between the second semiconductor chip body and the second redistribution group, the third insulating film pattern having a plurality of third openings exposing the bonding pads of the second bonding pad group, and having a plurality of fourth openings that expose ends of the redistributions of the second redistribution group; and
a fourth insulating film pattern covering the second redistribution group, the fourth insulating pattern having a plurality of fifth openings corresponding to the fourth openings, wherein the fifth openings expose portions of the redistributions of the second redistribution group.

10. A semiconductor package comprising:
a first semiconductor chip having a first semiconductor chip body including a first circuit region and first peripheral regions arranged around the first circuit region, the first semiconductor chip comprising:
a first bonding pad group arranged within the first circuit region, the first bonding pad group comprising a plurality of bonding pads; and
a first redistribution group comprising a plurality of redistributions, each redistribution of the first redistribution group being electrically connected to a respective one of the bonding pads of the first bonding pad group, wherein the redistributions of the first redistribution group extend to the first peripheral regions;
a semiconductor chip having a second semiconductor chip body including a second circuit region and second peripheral regions arranged around the second circuit region, the second semiconductor chip comprising:
a second bonding pad group arranged within the second circuit region, the second bonding pad group comprising a plurality of bonding pads;
a second redistribution group comprising a plurality of redistributions, each redistribution of the second redistribution group being electrically connected to a respective one of the bonding pads of the second bonding pad group, wherein the redistributions of the second redistribution group extend to the second peripheral regions; and
a plurality of through holes exposing portions of the redistributions of the second redistribution group;
a plurality of redistribution connection members electrically connecting the redistributions of the first redistribution group to the redistributions of the second redistribution group; and
a plurality of connection members connected to the redistributions of the second redistribution group via the through holes.

11. The semiconductor package according to claim 10, further comprising a substrate having a first surface provided with a plurality of contact pads, each contact pad being electrically connected to a respective one of the connection members.

12. The semiconductor package according to claim 10, wherein the first semiconductor chip further comprises:
a first insulating film pattern interposed between the first semiconductor chip body and the first redistribution group the first insulating film pattern having a plurality of first openings that expose the bonding pads of the first bonding pad group; and
a second insulating film pattern covering the first redistribution group, the second insulating film pattern having a plurality of second openings exposing portions of the redistributions of the first redistribution group where the redistribution connection members are formed.

13. The semiconductor package according to claim 10, wherein the second semiconductor chip further comprises:
a third insulating film pattern interposed between the second semiconductor chip body and the second redistribution group, the third insulating film pattern having a plurality of third openings exposing the bonding pads of the second bonding pad group, and having a plurality of fourth openings corresponding to the through hole; and
a fourth insulating film pattern covering the second redistribution group, the fourth insulating pattern having a plurality of fifth openings corresponding to the fourth openings, wherein the fifth openings expose portions of the redistributions of the second redistribution group.
